(19) United States
(12) Patent Application Publication
(10) Pub. No.: US 2026/0371689 A1
(43) Pub. Date: Nov. 19, 2026

(54) INTEGRATED BACKSIDE-FRONTSIDE POWER DELIVERY ARCHITECTURE

(71) Applicant: QUALCOMM Incorporated, San Diego, CA (US)

(72) Inventors: Bruce Hyeokjin LIM, San Diego, CA (US); Mukul GUPTA, San Diego, CA (US); Foua VANG, Sacramento, CA (US); Seungwan BAEK, San Diego, CA (US); Venkat NARAYANAN, San Diego, CA (US); Venugopal BOYNAPALLI, San Diego, CA (US)

(21) Appl. No.: 19/207,961

(22) Filed: May 14, 2025

(51) Int. Cl. H10D 64/23; H10W 20/43

(52) U.S. Cl. CPC H10D 64/254; H10W 20/43

(57) ABSTRACT

A chip includes a circuit block, first backside supply rails extending in a first direction, wherein the first backside supply rails are spaced apart from one another in a second direction perpendicular to the first direction, and second backside supply rails extending in the first direction under the circuit block, wherein the second backside supply rails are spaced apart from one another in the second direction. The chip also includes switches arranged along a boundary of the circuit block, wherein each of the switches is coupled between a respective one of the first backside supply rails and a respective one of the second backside supply rails.

### BACKGROUND

### Field

Aspects of the present disclosure relate generally to power delivery on a chip, and more particularly, to a backside-frontside power delivery architecture.

### BACKGROUND

A circuit block on a chip receives power from a power source (e.g., a battery or another power source) via a power delivery network. The power delivery network may be formed using frontside metal layers and/or backside metal layers on the chip. To conserve power, the chip may include switches configured to gate power to the circuit block when the circuit block is not active. Gating power to the circuit block conserves power by reducing leakage current when the circuit block is not active.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a circuit block, first backside supply rails extending in a first direction, wherein the first backside supply rails are spaced apart from one another in a second direction perpendicular to the first direction, and second backside supply rails extending in the first direction under the circuit block, wherein the second backside supply rails are spaced apart from one another in the second direction. The chip also includes switches arranged along a boundary of the circuit block, wherein each of the switches is coupled between a respective one of the first backside supply rails and a respective one of the second backside supply rails.

A second aspect relates to a chip. The chip includes a first backside supply rail, a second backside supply rail, and a switching transistor. The switching transistor includes a first source/drain, a second source/drain, a third source/drain, a first gate disposed between the first source/drain and the second source/drain, and a second gate disposed between the second source/drain and the third source/drain. The chip also includes a first backside via coupled between the second source/drain and the first backside supply rail, a second backside via coupled between the third source/drain and the first backside supply rail, and a frontside routing structure extending over the first source/drain and the second backside supply rail, wherein the first source/drain is coupled to the second backside supply rail through the frontside routing structure.

A third aspect relates to a chip. The chip includes a first backside supply rail, a second backside supply rail, and a switching transistor. The switching transistor includes a first source/drain, a second source/drain, and a first gate disposed between the first source/drain and the second source/drain. The chip also includes a first backside via coupled between the second source/drain and the first backside supply rail, a frontside routing structure extending over the first source/drain and the second backside supply rail, wherein the frontside routing structure is coupled to the first source/drain, and a vertical interconnect coupled between the frontside routing structure and the second backside supply rail.

### BRIEF DESCRIPTION OF THE DRAWINGS

FIG. 1A shows a side view of an example of a chip including a transistor and multiple layers according to certain aspects of the present disclosure.

FIG. 1B shows a side view of the chip of FIG. 1A further including multiple backside layers according to certain aspects of the present disclosure.

FIG. 2A shows a perspective view of the transistor implemented with a gate-all-around transistor according to certain aspects of the present disclosure.

FIG. 2B shows the perspective view of the transistor of FIG. 2A with a gate of the transistor shown in phantom according to certain aspects of the present disclosure.

FIG. 3 shows an example of a switch used for power gating according to certain aspects of the present disclosure.

FIG. 4 shows an exemplary implementation of the switch according to certain aspects of the present disclosure.

FIG. 5 shows the switch of FIG. 4 in which the orientation of the switch shown in FIG. 4 is flipped according to certain aspects of the present disclosure.

FIG. 6 shows another exemplary implementation of the switch according to certain aspects of the present disclosure.

FIG. 7 shows the switch of FIG. 6 in which the orientation of the switch shown in FIG. 6 is flipped according to certain aspects of the present disclosure.

FIG. 8 shows yet another exemplary implementation of the switch according to certain aspects of the present disclosure.

FIG. 9 shows an exemplary layout of backside supply rails and switches according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

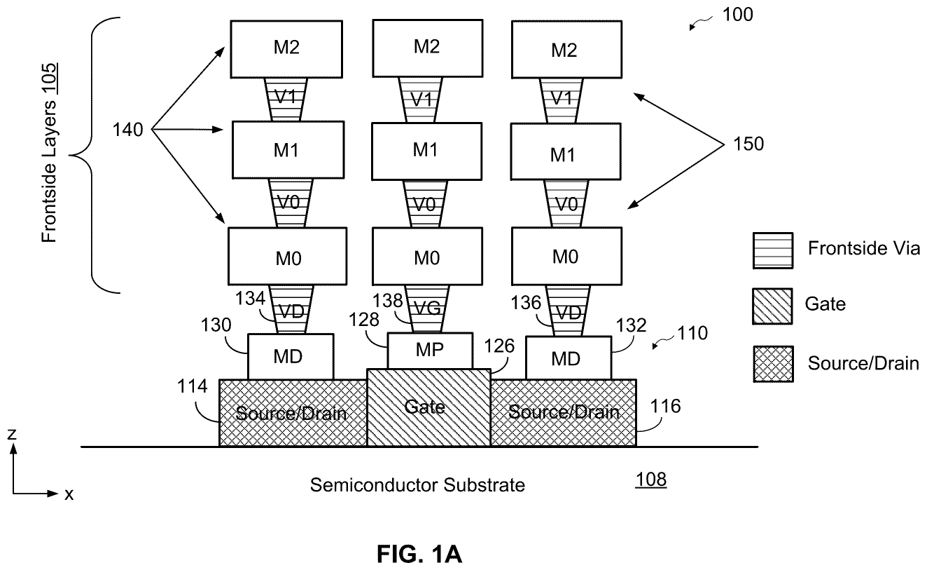

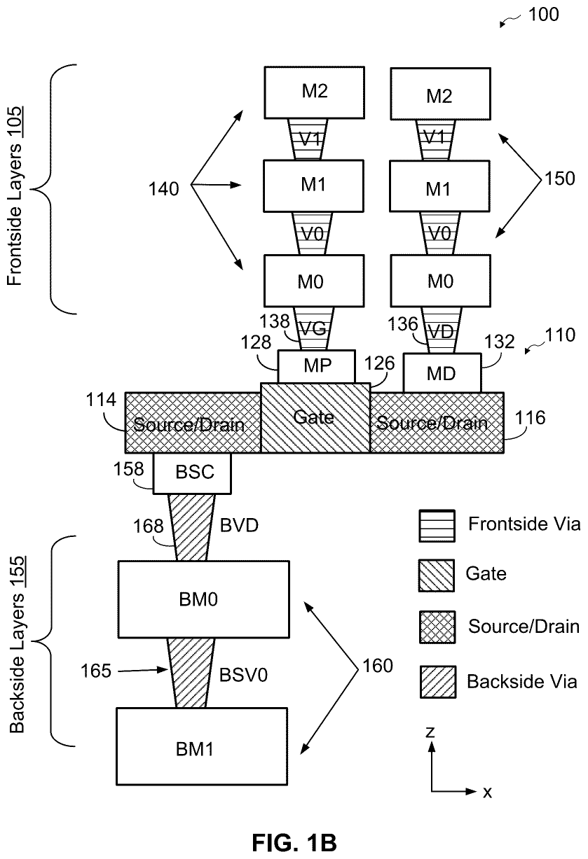

FIG. 1A shows a side view of an example of a chip 100 (e.g., a die) including a transistor 110 and multiple frontside layers 105 (also referred to as topside layers) according to certain aspects. Although one transistor 110 is shown in FIG. 1A for simplicity, it is to be appreciated that the chip 100 includes many transistors. As discussed further below, the transistor 110 may be implemented using a gate-all-around field-effect transistor (FET), a fin field-effect transistor (FinFET), a planar transistor, or another type of transistor. The frontside layers 105 are above the transistor 110 in the z direction shown in FIG. 1A. The transistor 110 and the frontside layers 105 may be formed on a semiconductor substrate 108 (e.g., silicon substrate).

In the example shown in FIG. 1A, the transistor 110 includes a gate 126, a first source/drain 114, and a second source/drain 116. As used herein, the term “source/drain” means a source, a drain, or both a source and a drain. The gate 126 may include a gate metal (e.g., a high-k metal gate (HKMG)), polysilicon, and/or another gate material. In this example, the gate 126 is disposed between the first source/drain 114 and the second source/drain 116. Each of the first source/drain 114 and the second source/drain 116 may include an epitaxial (epi) layer (e.g., epitaxially grown or deposited silicon) and/or another material.

As discussed further below, the transistor 110 may include one or more channels passing through or under the gate 126 and coupled between the first source/drain 114 and the second source/drain 116. The one or more channels may include one or more nanosheets, one or more fins, etc. The conductivity of the one or more channels is controlled by a voltage applied to the gate 126.

The transistor 110 may include a first spacer (not shown in FIG. 1A) between the gate 126 and the first source/drain 114 and a second spacer (not shown in FIG. 1A) between the gate 126 and the second source/drain 116. A spacer may also be referred to as a sidewall spacer or another term.

In this example, the chip 100 includes a first contact 130 formed on a top surface of the first source/drain 114 and a second contact 132 formed on a top surface of the second source/drain 116. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the frontside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, and so forth. Although three metal layers 140 (i.e., M0 to M2) are shown in FIG. 1A for ease of illustration, it is to be appreciated that the frontside layers 105 may include additional metal layers above metal layer M2. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The frontside layers 105 also includes vias 150 that provide coupling between the metal layers 140. The vias 150 include vias V0 and vias V1. In this example, the vias V0 provide coupling between metal layer M0 and metal layer M1, and the vias V1 provide coupling between metal layer M1 and metal layer M2. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the first contact 130 and metal layer M0, in which the via 134 couples the first contact 130 to metal layer M0. The chip 100 also includes a via 136 disposed between the second contact 132 and metal layer M0, in which the via 136 couples the second contact 132 to metal layer M0. In FIG. 1A, the via 138 is labeled “VG” and each of the vias 134 and 136 is labeled “VD”.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the frontside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1B shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1B, the top-most backside metal layer among the backside metal layers 160 is referred to as backside metal layer BM0. The backside metal layer immediately below backside metal layer BM0 is referred to as backside metal layer BM1, and so forth. Although two backside metal layers 160 (i.e., BM0 and BM1) are shown in FIG. 1B for ease of illustration, it is to be appreciated that the backside layers 155 may include additional metal layers below backside metal layer BM1. As shown in the example in FIG. 1B, backside metal layer BM0 may be thicker than frontside metal layer M0. For example, the backside metal layer BM0 may be used for power delivery in which the larger thickness reduces the resistance of the power delivery.

In the example in FIG. 1D, the chip 100 includes a backside contact 158 formed on a bottom surface (i.e., backside surface) of the first source/drain 114. The backside contact 158 may be formed (i.e., patterned) from a backside contact layer (labeled “BSC”) using, for example, lithographic and etching processes. The backside contact 158 is used to couple the first source/drain 114 to backside metal layer BM0. The backside contact 158 may be coupled to backside metal layer BM0 through backside via 168 (labeled “BVD”) disposed between the backside contact 158 and backside metal layer BM0. In this example, the backside via 168 provides a space between the backside contact 158 and backside metal layer BM0 in the z direction.

In the example in FIG. 1B, the backside layers 155 include vias 165 that provide coupling between the backside metal layers 160. In this example, the vias 165 include a via BSV0 that provides coupling between backside metal layer BM0 and backside metal layer BM1.

In certain aspects, the frontside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the frontside layers 105 are used for both signal routing and power distribution. It is to be appreciated that, in some implementations, both the frontside metal layers 140 and the backside metal layers 160 may be used for signal routing. In general, the present disclosure is not limited to a particular allocation of power routing and signal routing between the frontside layers 105 and the backside layers 155.

Although one gate 126 is shown in FIGS. 1A and 1B, it is to be appreciated that the transistor 110 may include multiple gates coupled to one another (e.g., through metal layer M0 or another metal layer). A transistor with multiple gates may be referred to as a multi-gate transistor, a multi-finger transistor, or another term.

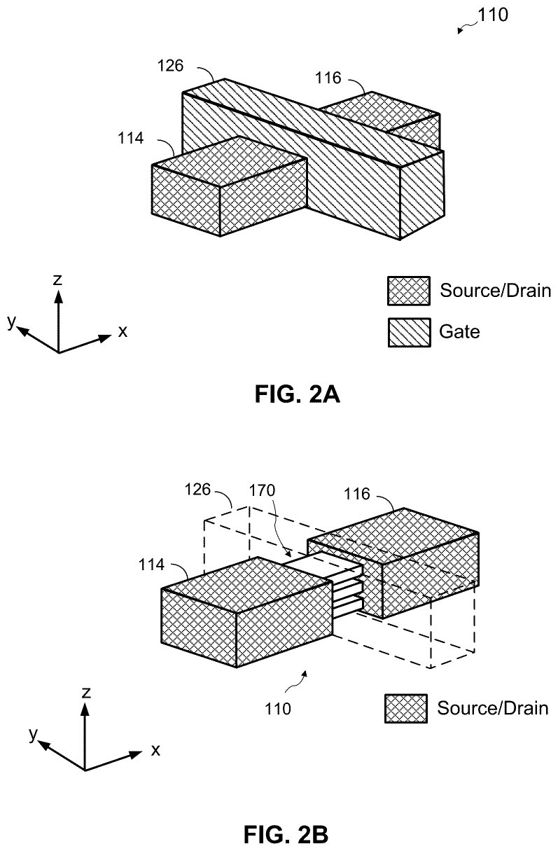

As discussed above, the transistor 110 may be implemented with a gate-all-around FET, a FinFET, a planar transistor, or another type of transistor. In this regard, FIGS. 2A and 2B show a perspective view in which the transistor 110 is implemented with a gate-all-around FET including one or more channels 170 passing through the gate 126 and coupled between the first source/drain 114 and the second source/drain 116. FIG. 2B shows the gate 126 in phantom in order to show the one or more channels 170.

In the example shown in FIG. 2B, each of the one or more channels 170 is surrounded on four sides by the gate 126. Each of the one or more channels 170 may include a nanosheet, a nanowire, or the like. In this example, the one or more channels 170 are stacked vertically and are spaced apart from one another in the z direction. However, it is to be appreciated that the present disclosure is not limited to this example. For example, for a FinFET implementation, each of the one or more channels 170 may be orientated vertically and the one or more channels 170 may be spaced apart from one another in the y direction.

It is to be appreciated that the first source/drain 114 and the second source/drain 116 are not limited to the exemplary shapes shown in FIGS. 2A and 2B. The first source/drain 114 and the second source/drain 116 may have other shapes (e.g., depending on the growth process and/or deposition process used to form the first source/drain 114 and the second source/drain 116).

In certain aspects, the chip 100 may employ power gating to reduce power consumption by gating power (i.e., switching off power) to a circuit block on the chip 100 when the circuit block is not active. Gating power to the circuit block reduces power consumption by reducing leakage current when the circuit block is not active.

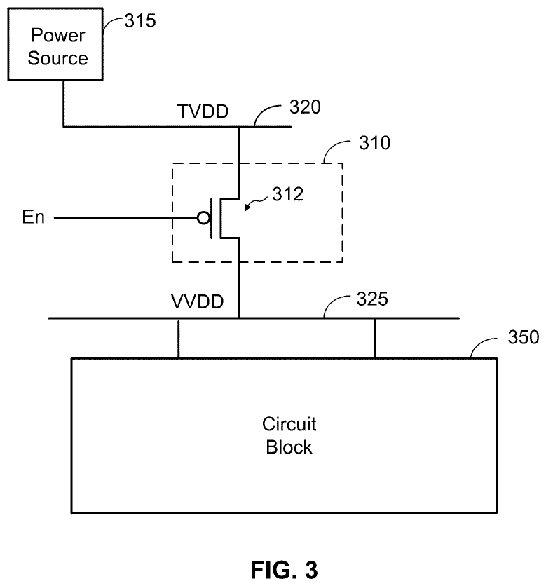

In this regard, FIG. 3 shows an example of a switch 310 (also referred to as a power switch) coupled between a first power network 320 and a second power network 325. Each of the power networks 320 and 325 may include one or more voltage supply rails. Although each of the power networks 320 and 325 is depicted as a line in FIG. 3 for ease of illustration, it is to be appreciated that each of the power networks 320 and 325 may have a two-dimensional structure or a three-dimensional structure to distribute power over an area of the chip 100. A power network with a two-dimensional structure or a three-dimensional structure may also be referred to as a power mesh, a power grid, a power distribution network, or another term. Although one switch 310 is shown in FIG. 3 for simplicity, it is to be appreciated that multiple switches may be coupled between the first power network 320 and the second power network 325. As discussed further below, both the first power network 320 and the second power network 325 may be formed in the backside metal layers 160 of the chip 100.

In this example, the first power network 320 is coupled to a power source 315 to receive power from the power source 315. The power source 315 may include a battery, one or more voltage regulators (e.g., a switching regulator and/or a low dropout (LDO) regulator), a power management integrated circuit (PMIC), or any combination thereof. The power source 315 may be integrated on the chip 100 or may be located off the chip 100. The power source 315 provides the first power network 320 with a supply voltage TVDD.

The circuit block 350 is coupled to the second power network 325 for receiving power. The circuit block 115 may include a memory, a processor (a central processing unit (CPU)), logic gates, or any combination thereof. The circuit block 350 may be coupled to the second power network 325 at multiple locations (e.g., using VD vias) to distribute power to various portions of the circuit block 350. For ease of illustration, the ground connections for the circuit block 350 are not shown in FIG. 3.

The on/off state of the switch 310 is controlled by an enable signal En from a power manager (not shown in FIG. 3). In the example in FIG. 3, the switch 310 includes a switching transistor 312 (e.g., a p-type field effect transistor (PFET)) having a source coupled to the first power network 320, a drain coupled to the second power network 325, and a gate configured to receive the enable signal En. As used herein, a “switching transistor” is a transistor used as a switch. For the example where the switching transistor 312 is implemented with a PFET, the switch 310 turns on when the enable signal En is low (e.g., ground potential) and turns off when the enable signal En is high (e.g., TVDD). However, it is to be appreciated that the switch 310 is not limited to this example. As used herein, an “enable signal” is a signal used to control the on/off state of a switch.

In this example, the power manager (not shown in FIG. 3) turns on the switch 310 using the enable signal En when the circuit block 350 is active. This allows the power source 315 to provide power to the circuit block 350 through the switch 310. The power manager turns off the switch 310 when the circuit block 350 is not active, which decouples the second power network 325 from the power source 315. In this case, the second power network 325 is power collapsed, which significantly reduces leakage current in the circuit block 350. In the example in FIG. 3, the second power network 325 has a supply voltage VVDD when the switch 310 is turned on. Assuming the current-resistor (IR) drop across the switch 310 is small, the supply voltage VVDD is approximately equal to the supply voltage TVDD. In this example, the second power network 325 may also be referred to as a gated power domain since power to the second power network 325 can be selectively gated using the switch 310.

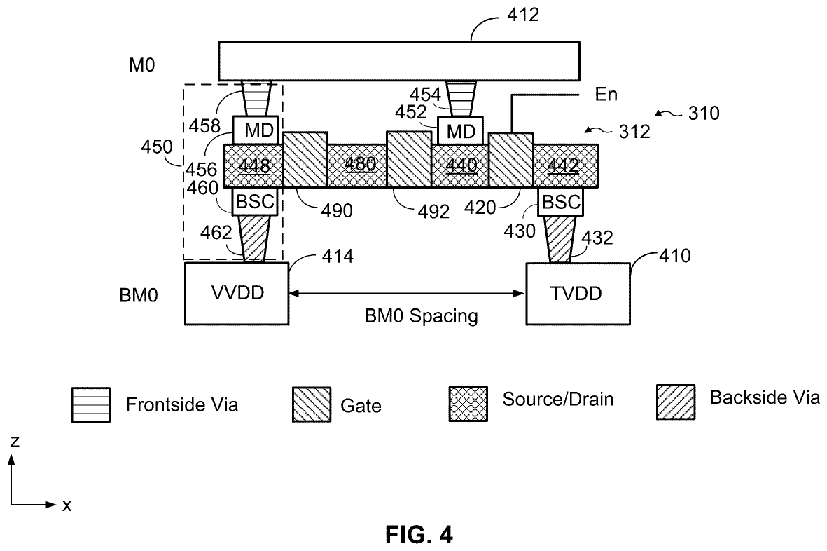

FIG. 4 shows a sideview of an exemplary implementation of the switch 310 according to certain aspects. In this example, the switch 310 includes the switching transistor 312 including a first source/drain 440, a second source/drain 442, and a first gate 420 disposed between the first source/drain 440 and the second source/drain 442. The switching transistor 312 also includes one or more channels (e.g., the one or more channels 170 shown in FIG. 2B) passing through the first gate 420 and coupled between the first source/drain 440 and the second source/drain 442. In this example, the first gate 420 is configured to receive the enable signal En. For example, the first gate 420 may be coupled to signal routing (not show) in metal layer M0 by a gate via (e.g., VG in FIGS. 1A and 1B). In this example, the first gate 420 receives the enable signal En from the power manager (not shown in FIG. 4) through the signal routing.

In this example, the switching transistor 312 turns on when the enable signal En is low (e.g., ground potential). In this case, the one or more channels (e.g., the one or more channels 170) of the switching transistor 312 conduct current between the first source/drain 440 and the second source/drain 442 when the first gate 420 is pulled low (e.g., ground potential). The switching transistor 312 turns off when the enable signal En is high (e.g., TVDD). In this case, the one or more channels of the switching transistor 312 conduct little to no current between the first source/drain 440 and the second source/drain 442 when the first gate 420 is pulled high (e.g., TVDD). Thus, in this example, the switch 310 turns on when the enable signal En is low and turns off when the enable signal En is high. However, it is to be appreciated that the switch 310 is not limited to this example. In other implementations, the switching transistor 312 may turn on when the enable signal En is high and turn off when the enable signal En is low.

In the example shown in FIG. 4, the first power network 320 (shown in FIG. 3) includes backside supply rail 410 formed in backside metal layer BM0 (e.g., using lithographic and etching processes). The second power network 325 (shown in FIG. 3) includes backside supply rail 414 formed in backside metal layer BM0 (e.g., using lithographic and etching processes).

In this example, the switching transistor 312 may be coupled between the backside supply rail 410 and the backside supply rail 414 to provide power gating between the first power network 320 and the second power network 325 (which may be coupled to the circuit block 350). However, the spacing between the backside supply rail 410 and the backside supply rail 414 (labeled “BM0 spacing” in FIG. 4) needs to meet a minimum spacing requirement for backside metal layer BM0 specified by the design rule checking (DRC) for the process technology used to fabricate the chip 100. The minimum spacing requirement for backside metal layer BM0 may be larger than the minimum spacing requirement for frontside metal layer M0 due to the larger thickness of backside metal layer BM0.

The minimum spacing requirement for backside metal layer BM0 may prevent both the backside supply rail 410 and the backside supply rail 414 from being placed close to the switching transistor 312. In the example shown in FIG. 4, the backside supply rail 410 is placed under the switching transistor 312, which allows the backside supply rail 410 to be coupled to the switching transistor 312 through a backside contact 430 and a backside via 432 disposed between the switching transistor 312 and the backside supply rail 410. However, the backside supply rail 414 is placed away from the switching transistor 312 in the x direction in order to meet the minimum spacing requirement for backside metal layer BM0. As a result, it is not possible to couple the backside supply rail 414 to the switching transistor 312 using a backside contact and a backside via between the switching transistor 312 and the backside supply rail 414.

To couple the backside supply rail 414 to the switching transistor 312 while meeting the minimum spacing requirement for backside metal layer BM0, the switch 310 includes a frontside routing structure 412 extending in the x direction. The frontside routing structure 412 may be formed in frontside metal layer M0 and/or another frontside metal layer (e.g., using lithographic and etching processes). In the example shown in FIG. 4, the backside supply rail 410 is placed under the second source/drain 442 of the switching transistor 312 while the backside supply rail 414 is coupled to the first source/drain 440 of the switching transistor 312 through the frontside routing structure 412 extending in the x direction. The frontside routing structure 412 allows the backside supply rail 414 to be placed far enough away from the backside supply rail 410 in the x direction to meet the minimum spacing requirement for backside metal BM0 while still being coupled to the first source/drain 440 of the switching transistor 312.

In the example in FIG. 4, the frontside routing structure 412 is formed in frontside metal layer M0 and extends over the first source/drain 440 and the backside supply rail 414. This allows the frontside routing structure 412 to provide supply voltage routing between the first source/drain 440 and the backside supply rail 414 in the x direction. In this example, the frontside routing structure 412 may also be referred to as a frontside rail or another term. The frontside routing structure 412 is discussed further below according to certain aspects.

In the example in FIG. 4, the backside supply rail 410 extends under the second source/drain 442. The switch 310 includes the backside contact 430 coupled to the bottom of the second source/drain 442 and the backside via 432 (e.g., BVD in FIG. 1B) coupled between the backside contact 430 and the backside supply rail 410. Thus, in this example, the second source/drain 442 is coupled to the backside supply rail 410 through the backside contact 430 and the backside via 432.

In the example in FIG. 4, the switch 310 includes a frontside contact 452 coupled to a top of the first source/drain 440 and a frontside via 454 (e.g., VD in FIGS. 1A and 1B) coupled between the frontside contact 452 and the frontside routing structure 412. Thus, in this example, the first source/drain 440 is coupled to the frontside routing structure 412 through the frontside contact 452 and the frontside via 454.

In the example in FIG. 4, the switch 300 also includes a vertical interconnect 450 coupling the frontside routing structure 412 to the backside supply rail 414 and extending in the z direction. The vertical interconnect 450 includes a source/drain 448, a frontside contact 456, a frontside via 458 (e.g., VD in FIGS. 1A and 1B), a backside contact 460, and a backside via 462 (e.g., BVD in FIG. 1B). The frontside contact 456 and the frontside via 458 couple the source/drain 448 to the frontside routing structure 412, and the backside contact 460 and the backside via 462 couple the source/drain 448 to the backside supply rail 414. Thus, in this example, the frontside routing structure 412 is coupled to the backside supply rail 414 through the frontside via 458, the frontside contact 456, the source/drain 448, the backside contact 460, and the backside via 462.

In this example, the vertical interconnect 450 coupling the frontside routing structure 412 to the backside supply rail 414 is spaced away from the first source/drain 440 of the switching transistor 312 in the x direction to meet the minimum spacing requirement between the backside supply rail 410 and the backside supply rail 414. In the example shown in FIG. 4, the chip 100 includes source/drain 480 and gates 490 and 492 in the space between the vertical interconnect 450 and the first source/drain 440 of the switching transistor 312. In this example, the gates 490 and 492 may be coupled to a ground or floating. The gates 490 and 492 and the source/drain 480 are used to fill the space between the source/drain 448 and the first source/drain 440 of the switching transistor 312. In this example, the space between the vertical interconnect 450 and the first source/drain 440 of the switching transistor 312 to meet the minimum spacing requirement for backside metal layer BM0 increases the area of the switch 310. Because the minimum spacing requirement for backside metal layer BM0 may be larger than the minimum spacing requirement for frontside metal layer M0 due to the larger thickness of backside metal layer BM0, the area penalty for the switch 310 may be higher than a switch that is coupled between supply rails formed in frontside metal layer M0.

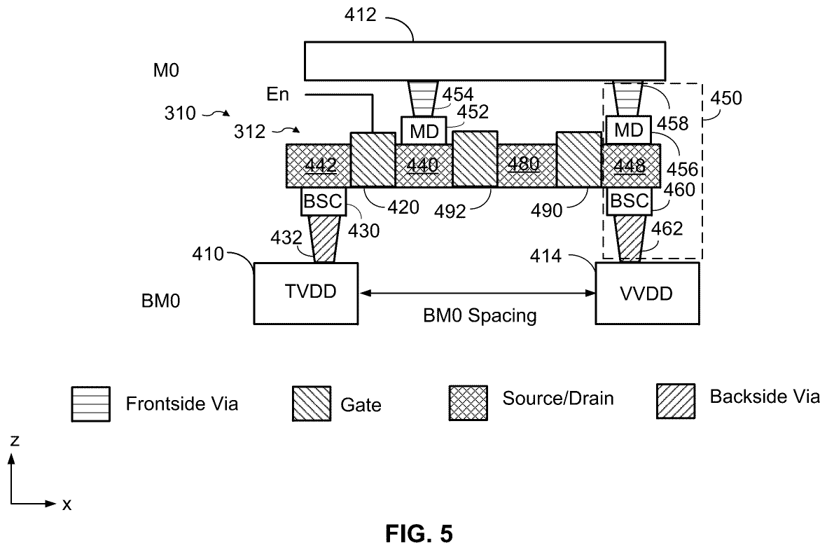

It is to be appreciated that the switch 310 is not limited to the exemplary orientation shown in FIG. 4. In this regard, FIG. 5 shows an example in which the orientation of the switch 310 is flipped in the x direction such that the backside supply rail 410 is located to the left of the backside supply rail 414 instead of to the right of the backside supply rail 414 in FIG. 4.

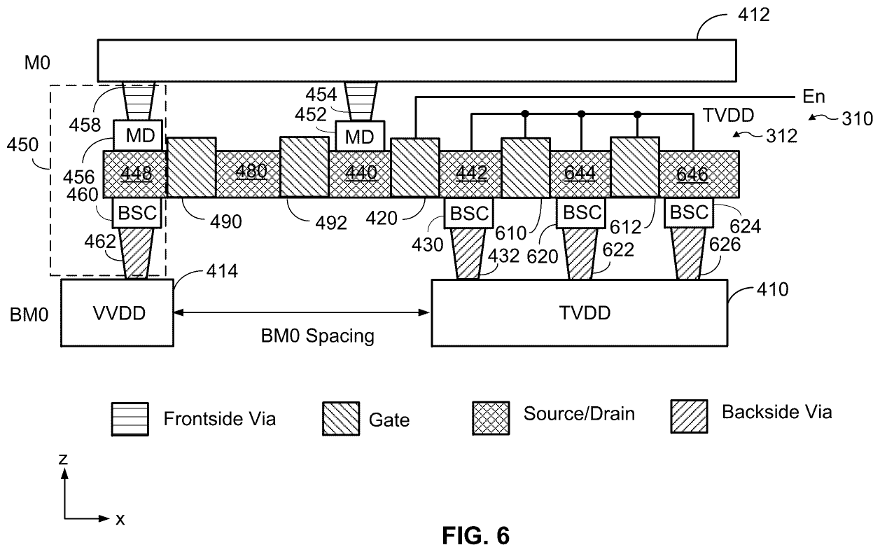

FIG. 6 shows the exemplary implementation of the switch 310 shown in FIG. 4 in which the switching transistor 312 further includes a third source/drain 644, a fourth source/drain 646, a second gate 610, and a third gate 612. In this example, the second gate 610 is disposed between the second source/drain 442 and the third source/drain 644, and the third gate 612 is disposed between the third source/drain 644 and the fourth source/drain 646.

In this example, the switch 310 further includes a backside contact 620 coupled to the bottom of the third source/drain 644 and a backside via 622 (e.g., BVD in FIG. 1B) coupled between the backside contact 620 and the backside supply rail 410. Thus, in this example, the third source/drain 644 is coupled to the backside supply rail 410 through the backside contact 620 and the backside via 622.

The switch 310 further includes a backside contact 624 coupled to the bottom of the fourth source/drain 646 and a backside via 626 (e.g., BVD in FIG. 1B) coupled between the backside contact 624 and the backside supply rail 410. Thus, in this example, the fourth source/drain 646 is coupled to the backside supply rail 410 through the backside contact 624 and the backside via 626.

In the example in FIG. 6, the second source/drain 442, the second gate 610, the third source/drain 644, the third gate 612, and the fourth source/drain 646 are coupled together (i.e., tied or shorted together). For example, the second source/drain 442, the second gate 610, the third source/drain 644, the third gate 612, and the fourth source/drain 646 may be coupled together through routing (not shown) in metal layer M0 and/or another structure.

In this example, the switching transistor 312 is coupled to the backside supply rail 410 through the backside vias 432, 622, and 626. The backside vias 622 and 626 provide additional backside vias for coupling the backside supply rail 410 to the switching transistor 312 compared with the example shown in FIG. 4. The additional backside vias 622 and 626 reduce the resistance between the backside supply rail 410 and the switching transistor 312. Furthermore, the additional backside vias 622 and 626 provide redundancy that reduces the risk of failure due to backside via misalignment. This is because, if one of the backside vias 432, 622, and 626 fails to make contact with the respective backside contact due to misalignment in the x direction, then the remaining backside vias may still make contact with the respective backside contacts, thereby avoiding failure.

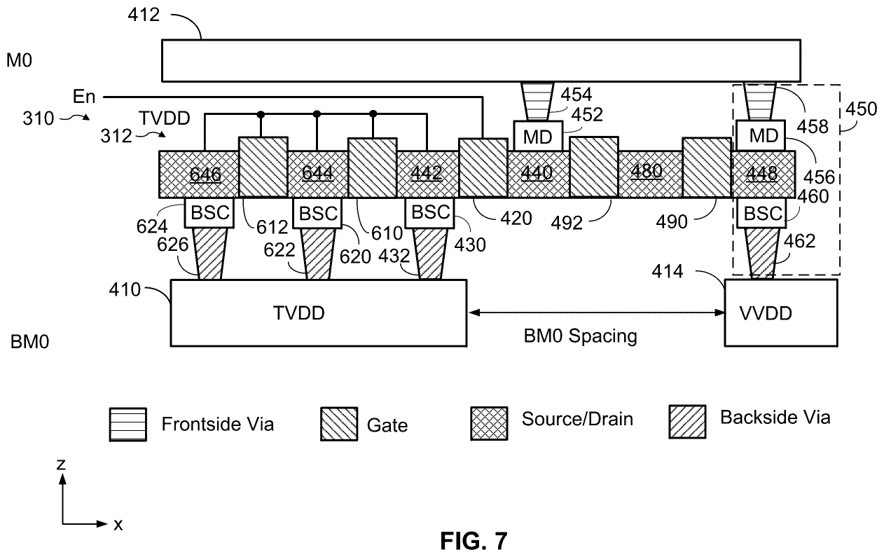

It is to be appreciated that the switch 310 is not limited to the exemplary orientation shown in FIG. 6. In this regard, FIG. 7 shows an example in which the orientation of the switch 310 is flipped in the x direction such that the backside supply rail 410 is located to the left of the backside supply rail 414 instead of to the right of the backside supply rail 414 in FIG. 6.

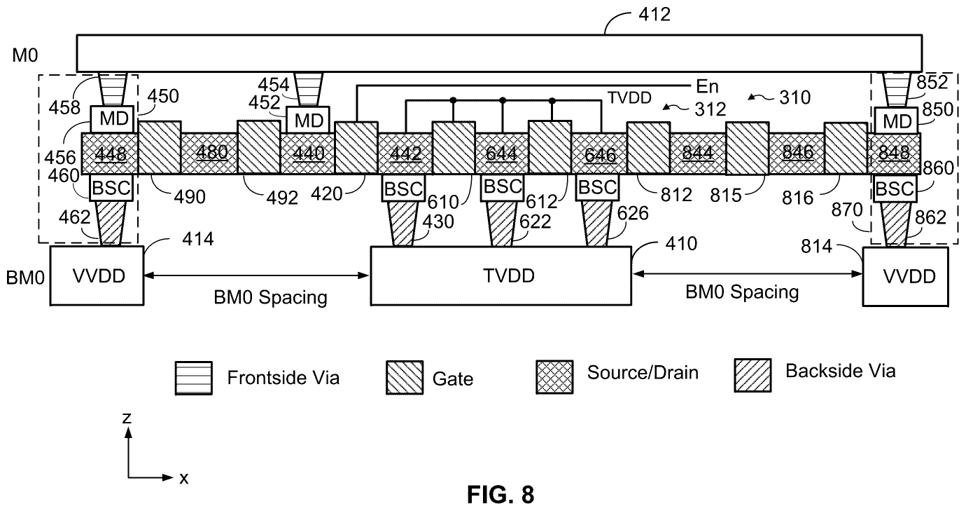

FIG. 8 shows the exemplary implementation of the switch 310 shown in FIG. 6 in which the chip 100 further includes backside supply rail 814 in the second power network 325 (shown in FIG. 3). In this example, the backside supply rail 410 (which is in the first power network 320) is located between the backside supply rails 414 and 814 (both of which are in the second power network 325).

In the example in FIG. 8, the switch 310 is also coupled between the backside supply rail 410 and the backside supply rail 814 through the frontside routing structure 412, which extends in the x direction over the backside supply rail 814. In this example, the switch 310 also includes a vertical interconnect 870 coupling the frontside routing structure 412 to the backside supply rail 814 and extending in the z direction. The vertical interconnect 870 includes a source/drain 848, a frontside contact 850, a frontside via 852 (e.g., VD in FIGS. 1A and 1B), a backside contact 860, a backside via 862 (e.g., BVD in FIG. 1B). The frontside contact 850 and the frontside via 852 couple the source/drain 848 to the frontside routing structure 412, and the backside contact 860 and the backside via 862 couple the source/drain 848 to the backside supply rail 814. Thus, in this example, the frontside routing structure 412 is coupled to the backside supply rail 814 through the frontside via 852, the frontside contact 850, the source/drain 848, the backside contact 860, and the backside via 862.

In this example, the source/drain 848 used to couple the frontside routing structure 412 to the backside supply rail 814 is spaced away from the fourth source/drain 646 of the switching transistor 312 to meet the minimum spacing requirement between the backside supply rail 410 and the backside supply rail 814. In the example shown in FIG. 8, the chip 100 includes source/drain 844, source/drain 846, and gates 812, 815, and 816 in the space between the source/drain 848 and the fourth source/drain 646 of the switching transistor 312. The gates 812, 815, and 816, the source/drain 844, and the source/drain 846 are used to fill the space between the source/drain 848 and the fourth source/drain 646 of the switching transistor 312.

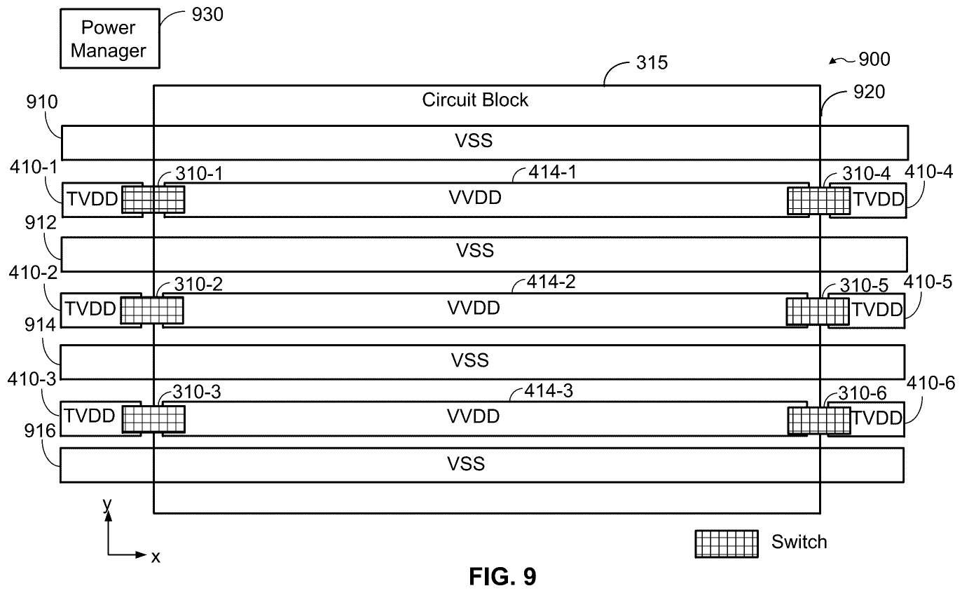

The chip 100 may include multiple instances of the switch 310 to provide power gating for the circuit block 350. In this regard, FIG. 9 shows a top view of an exemplary layout 900 of the circuit block 350 according to certain aspects. Although the circuit block 350 is shown having a rectangular shape in FIG. 9, it is to be appreciated that the circuit block 350 is not limited to a particular shape.

In this example, the chip 100 includes backside ground rails 910, 912, 914, and 916 (labeled “VSS”) extending under the circuit block 350 in the x direction. The backside ground rails 910, 912, 914, and 916 are formed in backside metal layer BM0 or another backside metal layer (e.g., using lithographic and etching processes). The backside ground rails 910, 912, 914, and 916 provide ground connections for devices (e.g., transistors) in the circuit block 350.

The chip 100 also includes backside supply rails 414-1, 414-2, and 414-3 (labeled “VVDD”) extending under the circuit block 350 in the x direction. Each of the backside supply rails 414-1, 414-2, and 414-3 may be a separate instance of the backside supply rail 414 shown in FIGS. 4 to 8. The backside supply rails 414-1, 414-2, and 414-3 are in the second power network 325 (shown in FIG. 3) and provide devices (e.g., transistors) in the circuit block 350 with the supply voltage VVDD when the circuit block 350 is active. The backside supply rails 414-1, 414-2, and 414-3 are formed in backside metal layer BM0 (e.g., using lithographic and etching processes). In the example shown in FIG. 9, the layout 900 alternates between the backside ground rails 910, 912, 914, and 916 and the backside supply rails 414-1, 414-2, and 414-3 in the y direction. However, it is to be appreciated that the present disclosure is not limited to this example.

The chip 100 also includes backside supply rails 410-1, 410-2, 410-3, 410-4, 410-5, and 410-6 (labeled “TVDD”) in the first power network 320 (shown in FIG. 3), which is coupled to the power source 315. Each of the backside supply rails 410-1, 410-2, 410-3, 410-4, 410-5, and 410-6 may be a separate instance of the backside supply rail 410 shown in FIGS. 4 to 8. In the example shown in FIG. 9, the backside supply rails 410-1, 410-2, and 410-3 are located to the left of the backside supply rails 414-1, 414-2, and 414-3, and the backside supply rails 410-4, 410, 5, and 410-6 are located to the right of the backside supply rails 414-1, 414-2, and 414-3. Each of the backside supply rails 410-1, 410-2, and 410-3 is aligned with a respective one of the backside supply rails 414-1, 414-2, and 414-3 in the y direction and spaced apart from the respective one of the backside supply rails 414-1, 414-2, and 414-3 in the x direction (e.g., by at least the minimum spacing requirement for backside metal layer BM0). Each of the backside supply rails 410-4, 410-5, and 410-6 is aligned with a respective one of the backside supply rails 414-1, 414-2, and 414-3 in the y direction and spaced apart from the respective one of the backside supply rails 414-1, 414-2, and 414-3 in the x direction (e.g., by at least the minimum spacing requirement for backside metal layer BM0).

The chip 100 also includes switches 310-1, 310-2, 310-3, 310-4, 310-5, and 310-6 for selectively power gating the backside supply rails 414-1, 414-2, and 414-3 coupled to the circuit block 350. Each of the switches 310-1, 310-2, 310-3, 310-4, 310-5, and 310-6 may be a separate instance of the switch 310 shown in FIGS. 4 to 8.

In the example shown in FIG. 9, the switch 310-1 is coupled between the backside supply rails 410-1 and 414-1, the switch 310-2 is coupled between the backside supply rails 410-2 and 414-2, and the switch 310-3 is coupled between the backside supply rails 410-3 and 414-3. In this example, the switches 310-1, 310-2, and 310-3 are located along the boundary 920 (e.g., left side) of the circuit block 350. However, it is to be appreciated that the present disclosure is not limited to this example.

In the example shown in FIG. 9, the switch 310-4 is coupled between the backside supply rails 410-4 and 414-1, the switch 310-5 is coupled between the backside supply rails 410-5 and 414-2, and the switch 310-6 is coupled between the backside supply rails 410-6 and 414-3. In this example, the switches 310-1, 310-2, and 310-3 are located along the boundary 920 (e.g., right side) of the circuit block 350. However, it is to be appreciated that the present disclosure is not limited to this example.

In the example shown in FIG. 9, the backside supply rails 414-1, 414-2, and 414-3 are contiguous across most or all of the circuit block 350 with the switches 310-1, 310-2, 310-3, 310-4, 310-5, and 310-6 located along the boundary 920 of the circuit block 350. This reduces the area penalty of the switches 310-1, 310-2, 310-3, 310-4, 310-5, and 310-6 within the circuit block 350 compared with globally distributed switches, which are distributed within the circuit block 350 and therefore increase the area of the circuit block 350. As discussed above, the frontside routing structure 412 used to meet the minimum BM0 spacing may increase the area of the switch 310. In this example, the area reduction provided by placing the switches 310-1, 310-2, 310-3, 310-4, 310-5, and 310-6 along the boundary 920 offsets the area increase of the switches due to the respective frontside routing structures.

In this example, a power manager 930 controls the on/off states of the switches 310-1, 310-2, 310-3, 310-4, 310-5, and 310-6 using the enable signal En discussed above. The power manager 930 may be coupled to the switches 310-1, 310-2, 310-3, 310-4, 310-5, and 310-6 through signal routing (not shown) in one or more of the frontside metal layers 140 (shown in FIGS. 1A and 1B). The power manager 930 may be implemented with a processor, gated logic, a field programmable gate array (FPGA), programmable logic devices (PLDs), discrete hardware circuits, and/or any combination thereof.

The power manager 930 is configured to turn on the switches 310-1, 310-2, 310-3, 310-4, 310-5, and 310-6 when the circuit block 350 is active. In this case, the switches 310-1, 310-2, 310-3, 310-4, 310-5, and 310-6 couple the backside supply rails 414-1, 414-2, and 414-3 in the second power network 325 to the backside supply rails 410-1, 410-2, 410-3, 410-4, 410-5, and 410-6 in the first power network 320, allowing the backside supply rails 414-1, 414-2, and 414-3 (and hence the circuit block 350) to receive power from the power source 315 (shown in FIG. 3).

The power manager 930 is configured to turn off the switches 310-1, 310-2, 310-3, 310-4, 310-5, and 310-6 when the circuit block 350 is not active to reduce leakage current. In this case, the switches 310-1, 310-2, 310-3, 310-4, 310-5, and 310-6 decouple from the backside supply rails 414-1, 414-2, and 414-3 in the second power network 325 from the backside supply rails 410-1, 410-2, 410-3, 410-4, 410-5, and 410-6 in the first power network 320, which power collapses the backside supply rails 414-1, 414-2, and 414-3.

Implementation examples are described in the following numbered clauses:
1. A chip, comprising:
   a circuit block;
   first backside supply rails extending in a first direction, wherein the first backside supply rails are spaced apart from one another in a second direction perpendicular to the first direction;
      second backside supply rails extending in the first direction under the circuit block, wherein the second backside supply rails are spaced apart from one another in the second direction; and
   switches arranged along a boundary of the circuit block, wherein each of the switches is coupled between a respective one of the first backside supply rails and a respective one of the second backside supply rails.
2. The chip of clause 1, wherein each of the switches comprises:
   a respective switching transistor, the respective switching transistor comprising:
      a respective first source/drain;
      a respective second source/drain; and
      a respective gate disposed between the respective first source/drain and the respective second source/drain, wherein the respective second source/drain is coupled to the respective one of the first backside supply rails; and
   a respective frontside routing structure extending in the first direction over the respective first source/drain, wherein the respective first source/drain is coupled to the respective one of the second backside supply rails through the respective frontside routing structure.
3. The chip of clause 2, wherein, for each of the switches, the respective one of the first backside supply rails extends under the respective second source/drain.
4. The chip of clause 3, wherein each of the switches further comprises a respective vertical interconnect coupled between the respective frontside routing structure and the respective one of the second backside supply rails.
5. The chip of clause 4, wherein each of the switches further comprises a respective frontside via coupled between the respective frontside routing structure and the respective first source/drain, and the respective frontside via is spaced apart from the respective vertical interconnect in the first direction.
6. The chip of clause 4 or 5, wherein, for each of the switches, the respective vertical interconnect comprises:
   a respective third source/drain;
   a respective frontside via coupled between the respective third source/drain and the respective frontside routing structure; and
   a respective backside via coupled between the respective third source/drain and the respective one of the second backside supply rails.
7. The chip of any one of clauses 1 to 6, wherein each of the switches comprises:
   a respective switching transistor;
   respective backside vias coupled between the respective switching transistor and the respective one of the first backside supply rails, wherein the respective backside vias are spaced apart from one another in the first direction; and
      a respective frontside routing structure extending in the first direction, wherein the respective switching transistor is coupled to the respective one of the second backside supply rails through the respective frontside routing structure.
8. The chip of any one of clauses 1 to 7, wherein the first backside supply rails and the second backside supply rails are formed in a same backside metal layer.
9. A chip comprising:
   a first backside supply rail;
   a second backside supply rail;
   a switching transistor, the switching transistor comprising:
      a first source/drain;
      a second source/drain;
      a third source/drain;
         a first gate disposed between the first source/drain and the second source/drain; and
         a second gate disposed between the second source/drain and the third source/drain;
      a first backside via coupled between the second source/drain and the first backside supply rail;
      a second backside via coupled between the third source/drain and the first backside supply rail; and
      a frontside routing structure extending over the first source/drain and the second backside supply rail, wherein the first source/drain is coupled to the second backside supply rail through the frontside routing structure.
10. The chip of clause 9, wherein the first gate is configured to receive an enable signal, and the second gate is shorted to the second source/drain and the third source/drain.
11. The chip of clause 9 or 10, further comprising a frontside via coupled between the first source/drain and the frontside routing structure.
12. The chip of any one of clauses 9 to 11, further comprising a vertical interconnect coupled between the frontside routing structure and the second backside supply rail.
13. The chip of clause 12, wherein the vertical interconnect comprises:
a fourth source/drain;
a frontside via coupled between the fourth source/drain and the frontside routing structure; and
a third backside via coupled between the fourth source/drain and the second backside supply rail.
14. The chip of clause 13, further comprising a third gate disposed between the first source/drain and the fourth source/drain, wherein the third gate is floating or coupled to a ground.
15. The chip of clause 14, wherein the first gate is configured to receive an enable signal, and the second gate is shorted to the second source/drain and the third source/drain.
16. The chip of any one of clauses 9 to 15, wherein the first backside supply rail and the second backside supply rail are formed in a same backside metal layer.
17. A chip comprising:
   a first backside supply rail;
   a second backside supply rail;
   a switching transistor, the switching transistor comprising:
      a first source/drain;
      a second source/drain; and
         a first gate disposed between the first source/drain and the second source/drain;
      a first backside via coupled between the second source/drain and the first backside supply rail;
      a frontside routing structure extending over the first source/drain and the second backside supply rail, wherein the frontside routing structure is coupled to the first source/drain; and
         a vertical interconnect coupled between the frontside routing structure and the second backside supply rail.
18. The chip of clause 17, wherein the vertical interconnect comprises:
   a third source/drain;
   a frontside via coupled between the third source/drain and the frontside routing structure; and
   a second backside via coupled between the third source/drain and the second backside supply rail.
19. The chip of clause 18, further comprising a second gate disposed between the first source/drain and the third source/drain, wherein the second gate is floating or coupled to a ground.
20. The chip of clause 19, wherein the first gate is configured to receive an enable signal.
21. The chip of any one of clauses 17 to 20, wherein the first backside supply rail and the second backside supply rail are formed in a same backside metal layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a circuit block;
first backside supply rails extending in a first direction, wherein the first backside supply rails are spaced apart from one another in a second direction perpendicular to the first direction;
second backside supply rails extending in the first direction under the circuit block, wherein the second backside supply rails are spaced apart from one another in the second direction; and
switches arranged along a boundary of the circuit block, wherein each of the switches is coupled between a respective one of the first backside supply rails and a respective one of the second backside supply rails.

2. The chip of claim 1, wherein each of the switches comprises:
a respective switching transistor, the respective switching transistor comprising:
a respective first source/drain;
a respective second source/drain; and
a respective gate disposed between the respective first source/drain and the respective second source/drain, wherein the respective second source/drain is coupled to the respective one of the first backside supply rails; and
a respective frontside routing structure extending in the first direction over the respective first source/drain, wherein the respective first source/drain is coupled to the respective one of the second backside supply rails through the respective frontside routing structure.

3. The chip of claim 2, wherein, for each of the switches, the respective one of the first backside supply rails extends under the respective second source/drain.

4. The chip of claim 3, wherein each of the switches further comprises a respective vertical interconnect coupled between the respective frontside routing structure and the respective one of the second backside supply rails.

5. The chip of claim 4, wherein each of the switches further comprises a respective frontside via coupled between the respective frontside routing structure and the respective first source/drain, and the respective frontside via is spaced apart from the respective vertical interconnect in the first direction.

6. The chip of claim 4, wherein, for each of the switches, the respective vertical interconnect comprises:
a respective third source/drain;
a respective frontside via coupled between the respective third source/drain and the respective frontside routing structure; and
a respective backside via coupled between the respective third source/drain and the respective one of the second backside supply rails.

7. The chip of claim 1, wherein each of the switches comprises:
a respective switching transistor;
respective backside vias coupled between the respective switching transistor and the respective one of the first backside supply rails, wherein the respective backside vias are spaced apart from one another in the first direction; and
a respective frontside routing structure extending in the first direction, wherein the respective switching transistor is coupled to the respective one of the second backside supply rails through the respective frontside routing structure.

8. The chip of claim 1, wherein the first backside supply rails and the second backside supply rails are formed in a same backside metal layer.

9. A chip comprising:
a first backside supply rail;
a second backside supply rail;
a switching transistor, the switching transistor comprising:
a first source/drain;
a second source/drain;
a third source/drain;
a first gate disposed between the first source/drain and the second source/drain; and
a second gate disposed between the second source/drain and the third source/drain;
a first backside via coupled between the second source/drain and the first backside supply rail;
a second backside via coupled between the third source/drain and the first backside supply rail; and
a frontside routing structure extending over the first source/drain and the second backside supply rail, wherein the first source/drain is coupled to the second backside supply rail through the frontside routing structure.

10. The chip of claim 9, wherein the first gate is configured to receive an enable signal, and the second gate is shorted to the second source/drain and the third source/drain.

11. The chip of claim 9, further comprising a frontside via coupled between the first source/drain and the frontside routing structure.

12. The chip of claim 9, further comprising a vertical interconnect coupled between the frontside routing structure and the second backside supply rail.

13. The chip of claim 12, wherein the vertical interconnect comprises:
a fourth source/drain;
a frontside via coupled between the fourth source/drain and the frontside routing structure; and
a third backside via coupled between the fourth source/drain and the second backside supply rail.

14. The chip of claim 13, further comprising a third gate disposed between the first source/drain and the fourth source/drain, wherein the third gate is floating or coupled to a ground.

15. The chip of claim 14, wherein the first gate is configured to receive an enable signal, and the second gate is shorted to the second source/drain and the third source/drain.

16. The chip of claim 9, wherein the first backside supply rail and the second backside supply rail are formed in a same backside metal layer.

17. A chip comprising:
a first backside supply rail;
a second backside supply rail;
a switching transistor, the switching transistor comprising:
a first source/drain;
a second source/drain; and
a first gate disposed between the first source/drain and the second source/drain;
a first backside via coupled between the second source/drain and the first backside supply rail;
a frontside routing structure extending over the first source/drain and the second backside supply rail, wherein the frontside routing structure is coupled to the first source/drain; and
a vertical interconnect coupled between the frontside routing structure and the second backside supply rail.

18. The chip of claim 17, wherein the vertical interconnect comprises:
a third source/drain;
a frontside via coupled between the third source/drain and the frontside routing structure; and
a second backside via coupled between the third source/drain and the second backside supply rail.

19. The chip of claim 18, further comprising a second gate disposed between the first source/drain and the third source/drain, wherein the second gate is floating or coupled to a ground.

20. The chip of claim 19, wherein the first gate is configured to receive an enable signal.
